(19) United States
(12) Patent Application Publication
(10) Pub. No.: US 2012/0132245 A1
(43) Pub. Date: May 31, 2012

(54) GLASS WINDOW FOR A VEHICLE HAVING A SOLAR CELL PORTION THEREWITH

(75) Inventor: Sang Young Kim, Hwaseong (KR)

(73) Assignee: HYUNDAI MOTOR COMPANY, Seoul (KR)

(21) Appl. No.: 13/073,796

(22) Filed: Mar. 28, 2011

(30) Foreign Application Priority Data
Nov. 30, 2010 (KR) 10-2010-0120948

(51) Int. Cl. H01L 31/042

(52) U.S. Cl. 136/244

(57) ABSTRACT

A glass window for a vehicle that is divided into a hidden area and a visible area is provided, which includes a glass portion, a solar cell portion provided inside the glass portion and composed of a substrate made of a flexible material and a plurality of solar cells disposed on an upper surface of the substrate in the hidden area, and a solar cell adhesive film disposed between the glass portion and the solar cell portion. Since solar cells are provided in a black band/hidden portion of the glass window instead of mounting the solar cells within a separate thick piece of glass of the roof of the vehicle, the amount of weight traditionally added to a vehicle can be minimized.

### CROSS-REFERENCE TO RELATED APPLICATION

This application is based on and claims priority from Korean Patent Application No. 10-2010-0120948, filed on Nov. 30, 2010 in the Korean Intellectual Property Office, the disclosure of which is incorporated herein in its entirety by reference.

### BACKGROUND OF THE INVENTION

1. Field of the invention

The present invention relates to a glass window for a vehicle, and more particularly, to a glass window for a vehicle having a solar cell portion that is provided in a hidden area of the glass to produce electric power.

2. Description of the Related Art

In general, glass windows for a vehicle are divided into a hidden area and a visible area. Conventional glass for a vehicle, as illustrated in FIG. 1A, includes a glass portion 810 of a transparent material, and a black band portion 820 provided on a border of an inner side surface of the glass portion 810 that is coated with a ceramic material or the like to form a hidden area which is not transparent.

This hidden area may be a sealant region of a self-bonding portion to which the glass portion 810 is attached or a black region that is used to improve the beauty of a rear glass or the like by hiding a heating element bus bar print coating.

Such a black band portion 820 is printed in a manner that a liquid ceramic coating solution is typically printed on flat glass that is cut according to a vehicle's design by a silk screen method, and is then adhered to the glass by performing a plastic forming at a required temperature range of about 600° C. to 700° C. This temperature range is well understood to be the best temperature range to provide optimal glass bending capabilities.

Alternatively, when the glass portion 910 is a laminated glass that is composed of an adhesive film 913 and two glass layers 911 and 912 as illustrated in FIG. 1B, a follow-up process at operating at about 120° C. to 140° C. in a pressurized environment of about 9-14 bars is typically performed.

Solar cells for vehicles are currently installed separately on a roof to produce electric power that is required by the vehicle. As understood by those skilled in the art, these separately installed solar cells are embodied within glass with a thickness of 3.2 mm or more to protect the solar cells. Thus, the addition of these solar cells to a vehicle increases the vehicle weight and thus decreases fuel efficiency.

### SUMMARY OF THE INVENTION

Accordingly, the present invention provides a glass window for a vehicle which embodies one or more solar cells in a black band portion of the glass window. Advantageously, by embodying the solar cell and the glass window as one in the same, the additional weight added by the addition of a solar cell to a vehicle can be reduced while at the same time providing sufficient protection to the solar cells.

In one aspect of the present invention, a glass window for a vehicle is provided that is divided into a hidden area and a visible area, the glass window having a glass portion and a solar cell portion. The solar cell portion of the present invention is embodied within the glass portion and is composed of a substrate of a flexible material and solar cells disposed on an upper surface of the substrate in the hidden area. Additionally, a solar cell adhesive film is disposed between the glass portion and the solar cell portion.

In some embodiments of the present invention, the substrate and the solar cell adhesive film may be provided within only the hidden area and glass portion may be composed of one glass layer. For example, the glass portion may be composed of two glass layers adhered to each other via an adhesive film. Alternatively, the glass portion may also be composed of a glass layer and a transparent film that are adhered to each other by an adhesive film.

In accordance with an embodiment of the present invention, the substrate of flexible material may be formed of a stainless steel foil, and the solar cells may be provided by coating the upper surface of the substrate with CIS(CuInSe₂) or CIGS(Cu(In,Ga)Se₂) compound. The substrate and the solar cell adhesive film may additionally be provided over the hidden area and the visible area, and the substrate may be made of a transparent material.

In some embodiments of the present invention, it may be advantageous to alternatively form the substrate from a polyimide or polyester (PET) film, and the solar cells may be provided by vapor-depositing amorphous silicon on the upper surface of the substrate.

In another aspect of the present invention, a glass window for a vehicle may be provided that is divided into a hidden area and a visible area, which includes a first glass portion and a second glass portion. In this embodiment, two adhesive films may be disposed between the first glass portion and the second glass portion, which stretch over the hidden area and the visible area. Additionally, a solar cell portion may be disposed between the two adhesive films and composed of a substrate of a flexible material and solar cells which are disposed on an upper surface of the substrate in the hidden area. More specifically, in some embodiments of this alternative embodiment, the first glass portion and the second glass portion may be composed of one glass layer.

In still another aspect of the present invention, a glass window for a vehicle is provided that is divided into a hidden area and a visible area, with a glass portion. The glass window in this alternative embodiment may also include a transparent film that is disposed inside the glass portion and two adhesive films which are disposed between the glass portion and the transparent film and is stretched over the hidden area and the visible area. Furthermore, a solar cell portion may be disposed between the two adhesive films and composed of a substrate of a flexible material and solar cells provided on an upper surface of the substrate in the hidden area.

In accordance with the illustrative embodiment described above the glass portion of the glass window may be made of one glass layer and the substrate may be disposed in the hidden area only in some cases.

In this case, the substrate may be formed of a stainless steel foil, and the solar cells may be provided by coating the upper surface of the substrate with CIS(CuInSe₂) or CIGS(Cu(In,Ga)Se₂) compound. The substrate may alternatively be formed of a polyimide or PET film, and the solar cells may be provided by vapor-depositing amorphous silicon on the upper surface of the substrate.

Additionally, in some embodiments of the present invention the substrate may be formed of a transparent material which stretches over the hidden are and the visible area.

Here, the transparent substrate may be formed of a polyimide or PET film, and the solar cells may be provided by vapor-depositing amorphous silicon on the upper surface of the substrate.

As described above, according to the present invention, since solar cells are provided in a black band portion that has been used only for the purpose of hiding in the related art, it is not required to separately mount the solar cells using thick glass on a roof, and thus the increase of the vehicle weight can be minimized.

### BRIEF DESCRIPTION OF THE DRAWINGS

The above and other objects, features and advantages of the present invention will be more apparent from the following detailed description taken in conjunction with the accompanying drawings, in which:

FIGS. 1A and 1B are exemplary cross-sectional views illustrating a conventional glass window for a vehicle;

FIG. 2 is a cross-sectional view illustrating an exemplary glass window for a vehicle according to a first exemplary embodiment of the present invention;

FIG. 3 is a cross-sectional view illustrating an exemplary glass window for a vehicle according to a second exemplary embodiment of the present invention;

FIG. 4 is a cross-sectional view illustrating an exemplary glass window for a vehicle according to a third exemplary embodiment of the present invention;

FIG. 5 is a cross-sectional view illustrating an exemplary glass window for a vehicle according to a fourth exemplary embodiment of the present invention;

FIG. 6 is a cross-sectional view illustrating an exemplary glass window for a vehicle according to a fifth exemplary embodiment of the present invention; and

FIG. 7 is a cross-sectional view illustrating an exemplary glass window for a vehicle according to a sixth exemplary embodiment of the present invention.

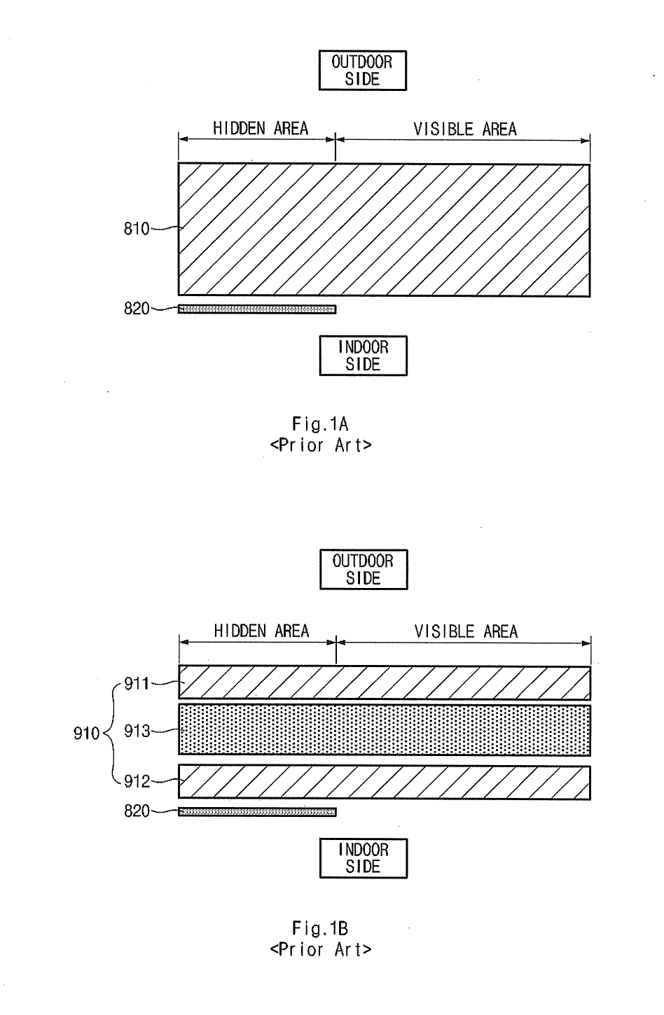

### DETAILED DESCRIPTION OF THE PREFERRED EMBODIMENTS

Hereinafter, preferred embodiments of the present invention will be described in greater detail with reference to the accompanying drawings. In the entire description of the present invention, the same drawing reference numerals are used for the same elements across various figures. A first embodiment of the invention is first described as a representative embodiment, and in other embodiments of the invention, only configurations that different from those of the first embodiment will be described.

It is understood that the term “vehicle” or “vehicular” or other similar term as used herein is inclusive of motor vehicles in general such as passenger automobiles including sports utility vehicles (SUV), buses, trucks, various commercial vehicles, watercraft including a variety of boats and ships, aircraft, and the like, and includes hybrid vehicles, electric vehicles, plug-in hybrid electric vehicles, hydrogen-powered vehicles and other alternative fuel vehicles (e.g. fuels derived from resources other than petroleum). As referred to herein, a hybrid vehicle is a vehicle that has two or more sources of power, for example both gasoline-powered and electric-powered vehicles.

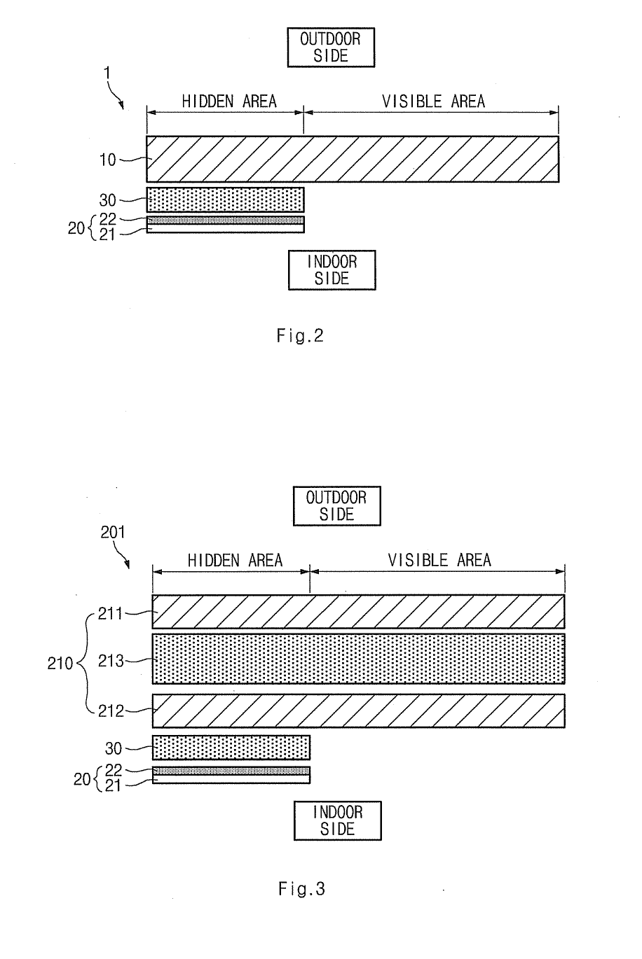

FIG. 2 is a cross-sectional view illustrating an exemplary glass window for a vehicle according to a first exemplary embodiment of the present invention.

As illustrated in FIG. 2, the glass window 1 for a vehicle in accordance with a first embodiment of the invention is divided into both a hidden area and a visible area, and includes a glass portion 10 and a solar cell portion 20. The solar cell portion 20 is disposed on an inner side border of the glass portion 10, and a solar cell adhesive film 30 is adhered between the glass portion 10 and the solar cell portion 20.

The glass portion 10 may be composed of one glass layer made of a transparent material, and stretches over the hidden area and the visible area.

In the illustrative embodiment of the present invention, the solar cell portion 20 is composed of a substrate 21 and solar cells 22 which are provided on an upper surface of the substrate 21, and stretches over just the hidden area.

In this case, the substrate 21 may be formed of a polyimide or polyester (PET) film of a transparent material which is flexible and has a good thermal resistance. The solar cells 22 may be provided by vapor-depositing amorphous silicon on the upper surface of the substrate 21. Here, on a lower surface of the substrate 21, silicon oxide (SiO₂) may be deposited, or anti-wearing coating, such as silane wet coating, may be performed to improve the substrate's anti-wear properties.

The solar cell adhesive film 30 serves to adhere the solar cell portion 20 to the inner side surface of the glass portion 10. Notably, the solar cell adhesive film 30 may be provided in the hidden area only in the same manner as the solar cell portion 20. Here, the solar cell adhesive film 30 maybe formed of a PVB (PolyVinyl Butyral) film or an EVA (EthyleneVinyl Acetate) film.

The glass portion 10, the solar cell adhesive film 30, and the solar cell portion 20, laminated together as discussed above, may be adhered to each other through a process which operates in environmental conditions of about 120° C. to 140° C. at a pressure of about 9-14 bars.

As discussed above, in this embodiment of the present invention, the substrate 21 of the solar cell portion 20 may be formed of a polyimide or PET film, and the solar cells 22 may be made of amorphous silicon. However, in some embodiments where it is deemed advantageous, the substrate 21 of the solar cell portion 20 may alternatively be formed of a stainless steel foil of a flexible material, and the solar cells 22 may be made of CIS(CuInSe₂) or CIGS(Cu(In,Ga)Se₂) compound.

FIG. 3 is a cross-sectional view illustrating an exemplary glass window for a vehicle according to a second exemplary embodiment of the present invention.

In the glass window 201 for a vehicle according to a second embodiment of the present invention, a glass portion 210 may be made in an alternative manor that is different from the glass portion according to the first embodiment of the present invention.

That is, the glass portion 10 according to the first embodiment is composed of one glass layers, whereas the glass portion 210 according to the second embodiment may be composed of two glass layers 211 and 212 which are adhered to each other by an adhesive film 213. In this case, the adhesive film 213 may be formed of a PVB (PolyVinyl Butyral) film or an EVA (EthyleneVinyl Acetate) film.

Further, the glass portion 210, the solar cell adhesive film 30, and the solar cell portion 220, laminated as discussed above, may be adhered to each other through a process operating in an environment having a temperature range of about 120 to 140° C. and a pressure of about 9-14 bars in the same manner as the first embodiment.

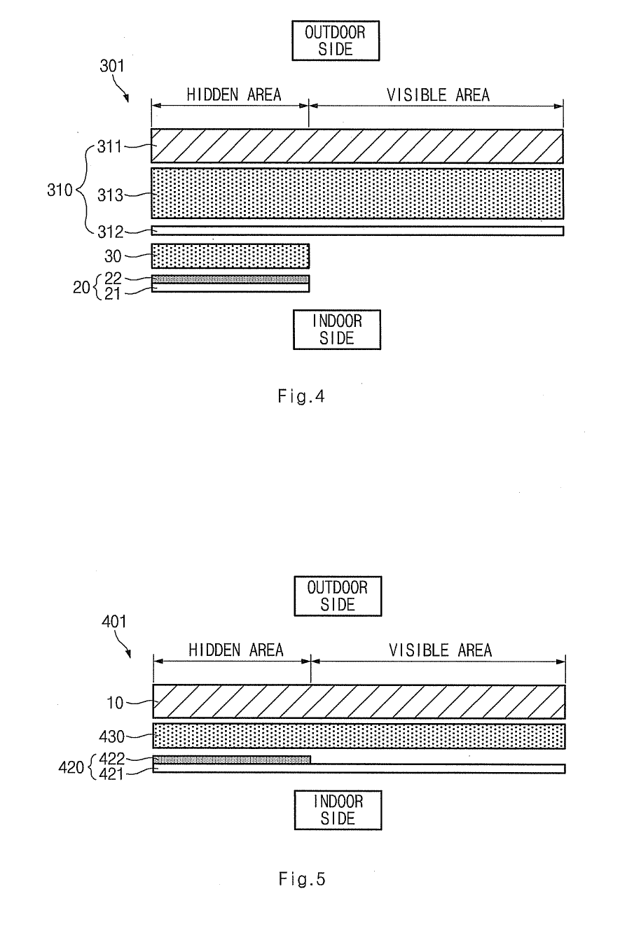

FIG. 4 is a cross-sectional view illustrating an exemplary glass window for a vehicle according to a third exemplary embodiment of the present invention.

In the glass window 301 for a vehicle as shown in accordance with an illustrative third embodiment of the present invention, a glass portion 310 is different from the glass portion according to the second embodiment of the present invention.

That is, the glass portion 210 according to the second embodiment is composed of two glass layers 211 and 212 which are adhered to each other via the adhesive film 213. Conversely, the glass portion 310 according to the third embodiment is composed of a glass layer 311 and a transparent film 312 which are adhered to each other via an adhesive film 313. In this case, the adhesive film 313 may be formed of a PVB film or an EVA film as well.

That is, in the glass portion 310 according to the third embodiment, the glass layer 212 that is positioned underneath the adhesive film 213 according to the second embodiment is replaced with the transparent film 312, and thus the entire thickness of the glass 301 can be reduced significantly without departing from the inventions initial purpose.

In this case, the transparent film 312 may be formed of a PET film, and thus it does not deteriorate the visibility in the visible area. During adhesion a primer process having a polyallylamine series may be performed on the upper surface of the transparent film 312, in order to improve the adhesivity to the adhesive film 313. Also, on a lower surface of the transparent film 312, silicon oxide (SiO₂) may be deposited. Alternatively, an anti-wearing coating, such as silane wet coating, may be applied to improve the anti-wear properties of the transparent film 312.

The glass portion 310, the solar cell adhesive film 330, and the solar cell portion 220, laminated as described above, may be again adhered to each other via a process operating in an environment with a temperature range of about 120° C. to 140° C. and a pressure of about 9-14 bars in the same manner as the first embodiment.

FIG. 5 is a cross-sectional view illustrating an exemplary glass window for a vehicle according to a fourth exemplary embodiment of the present invention.

In the glass window 401 for a vehicle according to a fourth embodiment of the present invention, a solar cell adhesive film 430 and a solar cell portion 420 are illustratively different from those according to the first embodiment of the present invention.

That is, the substrate 21 of the solar cell portion 20 according to the first embodiment is provided to the hidden area only, whereas the substrate 421 of the solar cell portion 420 according to the fourth embodiment may be disposed over the hidden area and additionally the visible area. To cope with this addition, the solar cell adhesive film 430 is also provided over the hidden area and the visible area to be adhered to the glass portion 10.

In this illustrative embodiment of the present invention, the substrate 421 may be formed again of a polyimide or PET film that is transparent to allow for visibility through the visible area. Furthermore, in this embodiment, the solar cells 422 may be provided by vapor-depositing amorphous silicon over the hidden area of the substrate 421 only.

On an upper surface of the substrate 421, in order to improve the adhesivity to the solar cell adhesive film 430, a primer process with polyallylamine series may be performed to upper surface of the substrate, and silicon oxide (SiO₂) may be deposited, or alternatively, an anti-wearing coating, such as silane wet coating, may be applied to the lower surface thereof, to improve the anti-wear properties of the lower surface.

The glass portion 10, the solar cell adhesive film 430, and the solar cell portion 420, laminated as above, may again be adhered to each other through a process operating in an environment having a temperature range of about 120° C. to 140° C. and a pressure of about 9-14 bars in the same manner as the first embodiment.

Here, since the thickness of the solar cells 422 is very thin (for example, 0.1 mm or less), no step is generated between the solar cell adhesive film 430 and the substrate 421 during the adhering process, and since the thickness of the substrate 421 is also very thin (for example, 0.2 mm or less), it is unlikely that there will be visibility problems such as perspective transformation due to a glass curvature which occurs after the adhering process has been completed.

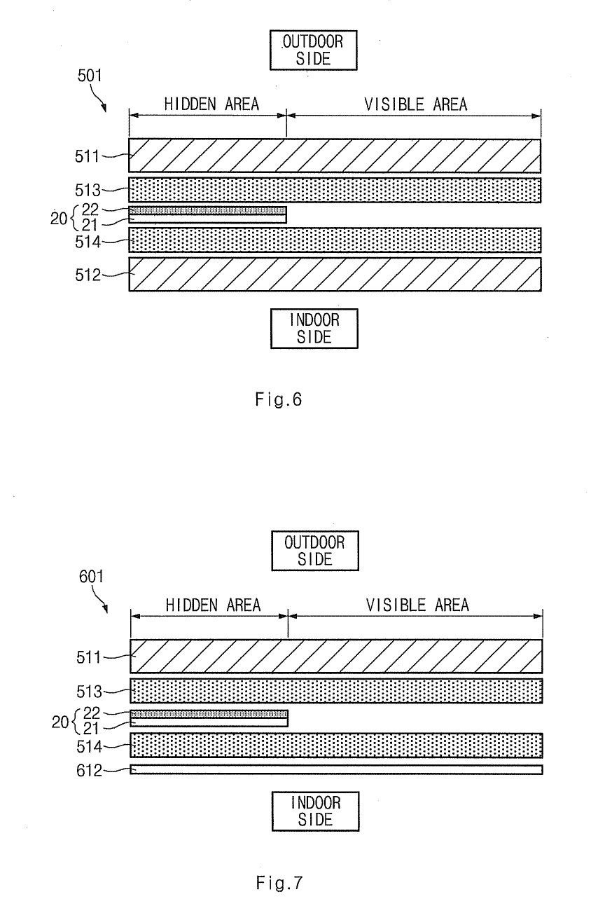

FIG. 6 is a cross-sectional view illustrating an exemplary glass window for a vehicle according to a fifth exemplary embodiment of the present invention.

The glass window 501 for a vehicle according to the fifth embodiment of the present invention includes a first glass portion 511 and a second glass portion 512, two adhesive films 513 and 514 provided between the first glass portion 511 and the second glass portion 512, and a solar cell portion 20 provided between the two adhesive films 513 and 514 in the hidden area.

In this illustrative embodiment of the present invention, the first glass portion 511 and the second glass portion 512 are respectively composed of one glass layer that stretches over the hidden area and the visible area.

The solar cell portion 20 is provided in the hidden area, and is composed of a substrate 21 and solar cells 22 provided on an upper surface of the substrate 21. The solar cell portion 20 may be adhered to inner sides of the first glass portion 511 and the second glass portion 512 by the two adhesive films 513 and 514.

In accordance with the fifth illustrative embodiment of the present invention, the substrate 21 may again be formed of a polyimide or PET film which is transparent, flexible and has a good thermal resistance. The solar cells 22 may again be provided by vapor-depositing amorphous silicon on the upper surface of the substrate 21.

On the other hand, on the lower surface of the substrate 21, a primer process with polyallylamine series may be performed in order to improve the adhesivity to the adhesive film.

The first glass portion 511 and the second glass portion 512, the adhesive films 513 and 514, and the solar cell portion 20, laminated as discussed above, are adhered to each other through a process operating again in an environment having a temperature range of about 120° C. to 140° C. and a pressure of about 9-14 bars in the same manner as the first embodiment.

Furthermore, in this embodiment of the present invention, the substrate 21 of the solar cell portion 20 may again be formed of a polyimide or PET film, and the solar cells 22 may be made of amorphous silicon. Alternatively, however, the substrate 21 of the solar cell portion 20 may also be formed of a stainless steel foil of a flexible material, and the solar cells 22 in this case may be made of CIS(CuInSe₂) or CIGS(Cu(In,Ga)Se₂) compound.

Although the substrate 21, in this illustrative embodiment of the present invention is provided in the hidden area only, the substrate may be provided not only in the hidden area but also in the visible area, and in this case, the substrate may be formed of a transparent polyimide or PET film to allow for visibility through the glass.

FIG. 7 is a cross-sectional view illustrating an exemplary glass window for a vehicle according to a sixth exemplary embodiment of the present invention.

In the sixth illustrative embodiment of the present invention, the second glass portion 512 according to the fifth embodiment is replaced by a transparent film 612.

That is, the glass window 601 for a vehicle according to the sixth embodiment includes a glass portion 511, a transparent film 612 provided inside the glass portion 511, two adhesive films 513 and 514 provided between the glass portion 511 and the transparent film 612, and a solar cell portion 20 provided in the hidden area between the two adhesive films 513 and 514.

In this exemplary embodiment, the glass portion 511 is composed of one glass layer, and the transparent film 612 is made of, e.g., a PET film. As described above, by replacing the second glass portion 512 according to the fifth embodiment by the transparent film 612, the entire thickness of the glass 601 can be reduced and accordingly the overall weight of the vehicle as well.

In accordance with this embodiment, a primer process having a polyallylamine series may be performed to an upper surface of the substrate 621 to improve the adhesivity to the adhesive film 514. On the lower surface thereof, silicon oxide (SiO₂) may be deposited, or alternatively an anti-wearing coating, such as silane wet coating, may be applied to improve the anti-wear properties.

Although the substrate 21 is provided in the hidden area only, the substrate may be provided not only in the hidden area but also in the visible area. Thus, the substrate should preferably be formed of a transparent material, such as, a polyimide or PET film to allow for visibility.

Advantageously, since solar cells are provided in, e.g., a black band portion, it is not required to separately mount the solar cells using thick glass on the roof of the vehicle, and thus the increase caused by added such a solar cell to the roof can be diminished.

Although preferred embodiments of the present invention have been described for illustrative purposes, those skilled in the art will appreciate that various modifications, additions and substitutions are possible, without departing from the scope and spirit of the invention as disclosed in the accompanying claims.

What is claimed is:

1. A glass window for a vehicle that is divided into a hidden area and a visible area, comprising:
a glass portion;
a solar cell portion provided inside the glass portion and composed of a substrate made of a flexible material and a plurality of solar cells provided on an upper surface of the substrate in the hidden area of the glass window; and
a solar cell adhesive film disposed between the glass portion and the solar cell portion.

2. The glass window for a vehicle according to claim 1, wherein the substrate and the solar cell adhesive film stretch over only the hidden area.

3. The glass window for a vehicle according to claim 2, wherein the glass portion is composed of one glass layer.

4. The glass window for a vehicle according to claim 3, wherein the substrate is formed of a stainless steel foil, and the plurality of solar cells are applied to the substrate by coating the upper surface of the substrate with either CIS(CuInSe2) or CIGS(Cu(In,Ga)Se2) compound.

5. The glass window for a vehicle according to claim 3, wherein the substrate is formed of either a polyimide or PET film, and the plurality of solar cells are applied to the substrate by vapor-depositing amorphous silicon on the upper surface of the substrate.

6. The glass window for a vehicle according to claim 2, wherein the glass portion is composed of two glass layers that are adhered to each other by an adhesive film.

7. The glass window for a vehicle according to claim 6, wherein the substrate is formed of a stainless steel foil, and the plurality of solar cells are applied to the substrate by coating the upper surface of the substrate with CIS(CuInSe2) or CIGS(Cu(In,Ga)Se2) compound.

8. The glass window for a vehicle according to claim 6, wherein the substrate is formed of either a polyimide or PET film, and the plurality of solar cells are applied to the substrate by vapor-depositing amorphous silicon on the upper surface of the substrate.

9. The glass window for a vehicle according to claim 2, wherein the glass portion is composed of a glass layer and a transparent film that are adhered to each other by an adhesive film.

10. The glass window for a vehicle according to claim 9, wherein the substrate is formed of a stainless steel foil, and the plurality of solar cells are applied to the substrate by coating the upper surface of the substrate with CIS(CuInSe2) or CIGS(Cu(In, Ga)Se2) compound.

11. The glass window for a vehicle according to claim 9, wherein the substrate is formed of either a polyimide or PET film, and the plurality of solar cells are applied to the substrate by vapor-depositing amorphous silicon on the upper surface of the substrate.

12. The glass window for a vehicle according to claim 1, wherein the substrate and the solar cell adhesive film are provided over the hidden area and the visible area, and the substrate is made of a transparent material.

13. The glass window for a vehicle according to claim 12, wherein the substrate is formed of a polyimide or PET film, and the solar cells are applied to the substrate by vapor-depositing amorphous silicon on the upper surface of the substrate.

14. A glass window for a vehicle that is divided into a hidden area and a visible area, comprising:
a first glass portion and a second glass portion;
two adhesive films provided between the first glass portion and the second glass portion, the two adhesive films stretching over the hidden area and the visible area; and
a solar cell portion provided between the two adhesive films and composed of a substrate made of a flexible material and a plurality of solar cells disposed on an upper surface of the substrate in the hidden area.

15. The glass window for a vehicle according to claim 14, wherein the first glass portion and the second glass portion are composed of one glass layer.

16. The glass window for a vehicle according to claim 15, wherein the substrate is disposed over only in the hidden area.

17. The glass window for a vehicle according to claim 16, wherein the substrate is formed of a stainless steel foil, and the plurality of solar cells are applied to the substrate by coating the upper surface of the substrate with CIS(CuInSe2) or CIGS(Cu(In, Ga)Se2) compound.

18. The glass window for a vehicle according to claim 16, wherein the substrate is formed of a polyimide or PET film, and the plurality of solar cells are applied to the substrate by vapor-depositing amorphous silicon on the upper surface of the substrate.

19. The glass window for a vehicle according to claim 15, wherein the substrate is made of a transparent material, and stretches over the hidden area and the visible area of the glass window.

20. The glass window for a vehicle according to claim 19, wherein the substrate is formed of a polyimide or PET film, and the plurality of solar cells are applied to the substrate by vapor-depositing amorphous silicon on the upper surface of the substrate.

21. A glass window for a vehicle that is divided into a hidden area and a visible area, comprising:
a glass portion;
a transparent film disposed on an inner side of the glass portion;
two adhesive films disposed between the glass portion and the transparent film, stretching over the hidden area and the visible area; and
a solar cell portion disposed between the two adhesive films and composed of a substrate made of a flexible material and a plurality of solar cells disposed on an upper surface of the substrate in the hidden area.

22. The glass window for a vehicle according to claim 21, wherein the glass portion is composed of one glass layer.

23. The glass window for a vehicle according to claim 22, wherein the substrate is disposed over only in the hidden area.

24. The glass window for a vehicle according to claim 23, wherein the substrate is formed of a stainless steel foil, and the plurality of solar cells are applied to the substrate by coating the upper surface of the substrate with CIS(CuInSe2) or CIGS(Cu(In, Ga)Se2) compound.

25. The glass window for a vehicle according to claim 23, wherein the substrate is formed of either a polyimide or PET film, and the plurality of solar cells are applied to the substrate by vapor-depositing amorphous silicon on the upper surface of the substrate.

26. The glass window for a vehicle according to claim 22, wherein the substrate is made of a transparent material, and stretches over the hidden area and the visible area.

27. The glass window for a vehicle according to claim 26, wherein the substrate is formed of either a polyimide or PET film, and the plurality of solar cells are applied to the substrate by vapor-depositing amorphous silicon on the upper surface of the substrate.
